(19) United States
(12) Patent Application Publication
(10) Pub. No.: US 2019/0056663 A1
(43) Pub. Date: Feb. 21, 2019

(54) EXPANSION POLYMERIZATION IMPRINTING GLUE FOR NANO-PRINTING

(71) Applicant: SOUTH UNIVERSITY OF SCIENCE AND TECHNOLOGY OF CHINA, Shenzhen (CN)

(72) Inventors: XING CHENG, Shenzhen (CN); Ziping LI, Shenzhen (CN); Zengju FAN, Shenzhen (CN); Yangqing TIAN, Shenzhen (CN); Bingqing LUO, Shenzhen (CN); Yulong CHEN, Shenzhen (CN); Shuimiao JING, Shenzhen (CN); Bo YU, Shenzhen (CN)

(73) Assignee: SOUTH UNIVERSITY OF SCIENCE AND TECHNOLOGY OF CHINA, Shenzhen (CN)

(21) Appl. No.: 15/754,690

(22) PCT Filed: Jul. 6, 2015
(86) PCT No.: PCT/CN2015/083408

§ 371 Date: Sep. 14, 2018

(30) Foreign Application Priority Data
May 26, 2015 (CN) 201510274285.2

(51) Int. Cl. G03F 7/039; G03F 7/00; C08L 67/00; C08K 5/00

(52) U.S. Cl. CPC G03F 7/039; G03F 7/0002; C08G 4/00; C08K 5/0058; C08K 5/0025; C08L 67/00

(57) ABSTRACT

An expansion polymerization imprinting glue for nano-imprinting. Raw materials required for the preparation of the expansion polymerization imprinting glue comprise a low polymer and an expansion monomer. Compared with the prior art, after the expansion monomer is introduced into the expansion polymerization imprinting glue for nano-imprinting, the expansion monomer can be polymerized with the low polymer, the volume change of the imprinting glue after polymerization can be adjusted, and accordingly the volume shrinkage after the imprinting glue is cured is reduced or even eliminated; and the imprinting glue having zero curing shrinkage or volume expansion can be obtained by adjusting the content of the expansion monomer. The imprinting glue can effectively reduce the residual stress in a micro-nano pattern, and the generation of pattern defects in the nano-imprinting demolding process caused by the residual stress is reduced while accurate pattern copying is implemented.

### TECHNICAL FIELD

The present invention relates to the technical field of nano-imprinting technology, in particular to an expansion polymerization imprint resist for nano-imprinting.

### BACKGROUND

Micro-nano manufacturing technology is an advanced manufacturing technology having a wide range of influence, which covers scopes including microelectronics, optoelectronics, micro-nano optics, bioengineering and other major engineering fields. It is a key issue concerning about the industrialization of many high-technologies to manufacture micro-nano patterns and structures on a large scale with low costs. Nano-imprinting technology is a micro-nano manufacturing technology developed rapidly in the world in recent years. It has been highly concerned by academia and industry for its features including high precision of patterns, simple process and equipment, and high process throughput, and considered to be one of the next most potential technologies in manufacturing nanostructures on large scale with low costs.

Nano-imprinting technology allows micro-nano patterns on a template to transfer onto a substrate through an imprint resist by replicating micro-nano surface structures by using a mechanical imprinting manner. The nano-imprinting can be divided into thermoplastic nano-imprinting and UV-curing nano-imprinting according to different processes and materials.

During a thermoplastic nano-imprinting process, the imprint resist begins to melt when the temperature thereof reaches its glass transition temperature, and fills the micro-nano structures on the surface of the template. After being cooled to a temperature below the glass transition temperature, the imprint resist is cured to form a micro-nano pattern. An obvious volume shrinkage occurs since the imprint pattern changes from a liquid state to a solid state, resulting in a decrease in the fidelity of the pattern. The entire imprint cycle is long due to the need of undergoing heating and cooling processes, resulting in a low process throughput. Meanwhile, the costs and difficulties in processing are increased due to the need for heating and high pressure in thermoplastic nano-imprinting, which is not suitable for patterning of silicon chips with large area.

UV-curing nano-imprinting technology overcomes some of the problems described above and can be performed at room temperature under low pressure. It has a short cycle, simple process and high process throughput and can be used in the patterning of silicon chips with large area. It is considered as the first technology that has been industrialized on large scale in nano-imprinting technologies. Conventional photo-curable imprint resist systems typically consist of oligomers, photoinitiators, diluents and additives. Wherein, the oligomer, which is the main body of a photo-curable product, is a photosensitive resin with low molecular weight having groups capable of undergoing a photo-curing reaction such as unsaturated double bonds or epoxy groups. The oligomers exist at a van der Waals distance with each other before being cured. After being cured, the molecules react with each other, double bonds or epoxy groups are opened, and covalent bonds are formed between the molecules. Volume shrinkage occurs in the imprint resist system after being cured since the covalent bond distance is much smaller than the Van der Waals distance. The volume shrinkage not only leads to a decrease in the fidelity of the imprint pattern, in addition, the shrinking force existed in the imprint resist reduces the adhesion strength between the imprint resist and the substrate, resulting in a delamination inside the imprint resist. Meanwhile, the shrinkage of the imprint resist increases the difficulties in demolding, leading to an increased defect ratio in pattern replication after demolding.

As the epoxy oligomers in traditional imprint resists are ring-opening polymers, the volume shrinkage is relatively low, however, still cannot be completely eliminated. The volume shrinkage can only be reduced to some extent by using other methods of reducing volume shrinkage, such as reducing the concentration of functional groups in the reaction system, adding polymers with high molecular weight for toughening and adding inorganic fillers etc., however, cannot be completely eliminated. Therefore, it is necessary to solve the key problem of volume shrinkage of the imprint resist when being cured as described above as soon as possible to achieve the important role of nano-imprinting technology in integrated circuit manufacturing and micro-nano processing. In addition, there needs to develop a new imprint resist system which has no volume shrinkage when being cured to guarantee a high pattern fidelity and to decrease the defects in pattern replication caused by the volume shrinkage of imprint resist.

### SUMMARY OF THE INVENTION

The technical problem to be solved by the present invention is to provide an expansion polymerization imprint resist for nano-imprinting that can effectively reduce the volume shrinkage of the imprint resist when being cured in view of the state of the art.

The technical solution adopted by the present invention to solve the technical problem described above is as following: an expansion polymerization imprint resist for nano-imprinting, raw materials required for the preparation thereof comprise an oligomer, and further comprise an expansion monomer.

The expansion monomer mentioned in the above technical solution is a monomer which expands in volume after being cured. That is, there is a type of monomer which expands in volume during the polymerization process. Such type of polymerization reaction is called expansion polymerization reaction. The monomer that can undergo an expansion polymerization reaction is called expansion monomer. Only during the ring-opening polymerization reaction process, not only the volume shrinkage process exists, but also a volume expansion process occurs with the opening of the ring. Therefore, all the expansion reactions studied in the present invention are ring-opening polymerization reactions including cationic, anionic and free-radical ring-opening polymerization reaction, among which the most widely used and studied is the cationic ring-opening polymerization reaction.

Wherein the expansion monomer accounts for 10-200%, for example, 50%, 70%, 100%, 120%, 150%, 180%, of the weight of the oligomer. The oligomer and the expansion monomer are copolymerized since an expansion monomer is introduced into the UV-curable imprint resist system, thereby the volume expansion occurred during the polymerization process of the expansion monomer can be used to counteract the volume shrinkage occurred when the imprint resist is being polymerized. The volume change of the imprint resist after polymerization can be effectively regulated and an imprint resist with no shrinkage and volume expansion after being cured can even be obtained by adding an expansion monomer at such compounding ratio.

Wherein the expansion polymerization imprint resist for nano-imprinting further comprises a photoinitiator, wherein the photoinitiator accounts for 0.1-5%, for example, 0.5%, 0.8%, 1%, 1.5%, 2%, 2.5%, 3%, 3.5%, 4%, 4.5%, of the total weight of the oligomer and the expansion monomer.

Preferably, the photoinitiator accounts for 1-2% of the total weight of the oligomer and the expansion monomer.

Preferably, the photoinitiator is a cationic photoinitiator.

Preferably, the photoinitiator is one selected from the group consisting of aryldiazonium salt, diaryliodonium salt, triarylsulfonium salt and aryl ferrocenium salt, or a mixture of at least two thereof.

Preferably, the photoinitiator is a mixture of a diaryliodonium salt and a triarylsulphonium salt.

The photoinitiator is an important component of the imprint resist system, which can absorb radiation energy and undergo a chemical reaction upon excitation to generate free-radicals or cations having polymerization initiating ability to initiate a polymerization reaction. The selection of a photoinitiator needs to be matched with light source and polymerization characteristics of polymerization monomer. The photoinitiator is divided into free-radical photoinitiator and cationic photoinitiator. Free-radical photoinitiator including pyrolysis type photoinitiator and hydrogen abstraction type photoinitiator is selected when the oligomer and the expansion monomer in the imprint resist system are free-radical polymerization-type. Oligomer and expansion monomer of cationic polymerization-type are preferably selected in the imprint resist system of the present invention, and thus cationic type photoinitiator is preferably used. Cationic type photoinitiator allows molecules to undergo a photolytic reaction by absorbing light energy to form super proton acids or Lewis acids, initiating a polymerization reaction of the cationic oligomer and the expansion monomer. Cationic photoinitiator can be aryldiazonium salt, diaryliodonium salt, triarylsulfonium salt, aryl ferrocenium salt and the like. Diaryliodonium salt and triarylsulfonium salt are preferably selected to use in the present invention, and both of the two types can initiate both cationic polymerization and free-radical polymerization. In order to increase the utilization ratio of UV light sources by the photoinitiator, a small amount of photosensitive agent can be added to the imprint resist system.

Wherein the expansion polymerization imprint resist for nano-imprinting further comprises a diluent, wherein the diluent is added at such an amount that the viscosity of the imprint resist is allowed to be 1-10000 cP. In general, for spin-coated thin films with a thickness of several hundred nanometers, the viscosity of the imprint resist is typically several centipoises.

The diluent in the imprint resist including two types, inactive diluent and active diluent, can be used to adjust the viscosity of the imprint resist to facilitate the formation of film and the adjustment of the thickness of the film. Inactive diluent is generally a small molecular organic compound that does not participate in photopolymerization reaction. Most is volatilized during the spin-coating process and is removed during the soft-baking process. PGMEA and PGME are preferred. Active diluent, which generally contains polymerizable functional groups, is divided into two types, free-radical type and cationic type. Cationic type, which is predominantly vinyl ethers and epoxy diluents, is preferably selected when selecting active diluent since oligomer and expansion monomer of cationic polymerization-type are preferred in the present invention.

In addition to the oligomer, expansion monomer, photoinitiator and diluent described above, a cross-linking agent and other auxiliary agents can be added to the imprint resist system in order to improve various physical properties of the formed film after curing. The cross-linking agent reacts with the oligomer and the expansion monomer, creating a three-dimensional network structure, which can enhance the strength of the film after curing. Cross-linking agent generally contains a plurality of functional groups. Cationic polymerization-type cross-linking agent such as cross-linking agents having four or more epoxy groups are preferably selected in the present invention. Auxiliary agents are used to improve the performances of the imprint resist system in the process of production, application, transportation and storage, which can generally be defoaming agent, leveling agent, dispersant, matting agent, polymerization inhibitor and the like. One or more auxiliary agents as described above can be added according to the needs in actual applications.

Wherein all monomers capable of undergoing an expansion polymerization reaction are cyclic compounds. That is, the expansion monomer is one selected from the group consisting of spiro orthoester compound, spiro orthocarbonate compound, bicyclic orthoester compound and bicyclic lactone compound, or a mixture of at least two thereof.

Wherein the spiro orthoester compound is selected from the spiro orthoester monomer represented by formula I or derivatives thereof, the unsaturated spiro orthoester monomer represented by formula II or derivatives thereof;

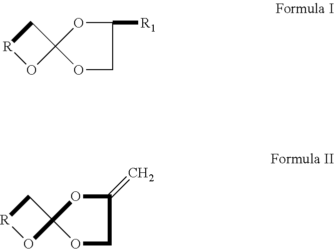

in formula I, R=—(CH₂)ₙ—, n=2, 3 or 4;
R₁=hydrogen, alkyl, haloalkyl, phenyl, anisyl or o-methyl anisyl;
in formula II, R=—(CH₂)ₙ—, n=2, 3 or 4;
wherein what represented by formula I is a representative spiro orthoester monomer, in addition, the spiro orthoester monomer further comprises various derivatives of the expansion monomer as described above, for example, the derivatives of the spiro orthoester monomer are selected from at least one of the followings:

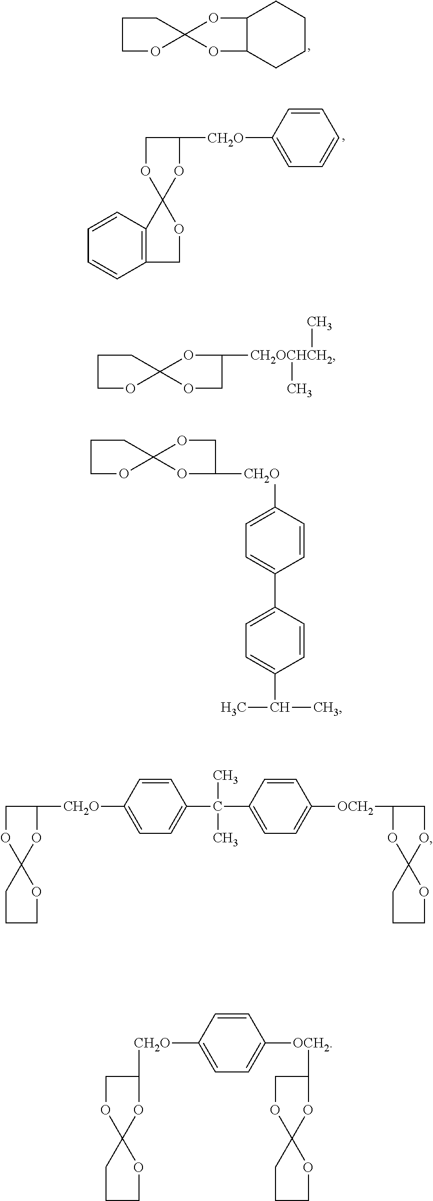

The Spiro orthoester monomer as described above can undergo cationic double ring-opening polymerization reaction under the action of an initiator. The distance between the two ends of the molecule is increased due to the opened double ring, thus compensating or even surpassing the volume shrinkage resulting from the change of monomer molecule from the van der Waals force distance to covalent bond distance between monomer units.

In addition, the unsaturated spiro orthoester monomer represented by formula II and derivatives thereof undergo a free-radical ring-opening polymerization reaction under the action of an initiator. Cationic ring-opening polymerization-type expansion monomer is preferably selected in the present invention due to the lack of research on free-radical ring-opening polymerization reaction.

Wherein the spiro orthocarbonate compound is selected from the spiro orthocarbonate monomer represented by formula III or derivatives thereof, an unsaturated spiro orthocarbonate monomer or derivatives thereof;

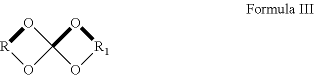

in formula III, R=—(CH₂)ₙ—, n=1, 2, 3, 4;
R₁=—(CH₂)ₙ—, n=1, 2, 3, 4; wherein R₁ and R may be the same group or may also be different groups.
Wherein the H atoms linked to the C atoms of R and R₁ may also be substituted by one or more groups of alkyl, cyclohexyl, alkylhydroxyl, nitro and phenyl to generate a corresponding derivative;
in addition to the derivatives with simple structures as described above, there are some derivatives with complex structures, for example, the derivatives of the spiro orthocarbonate monomer are selected from at least one of the followings:

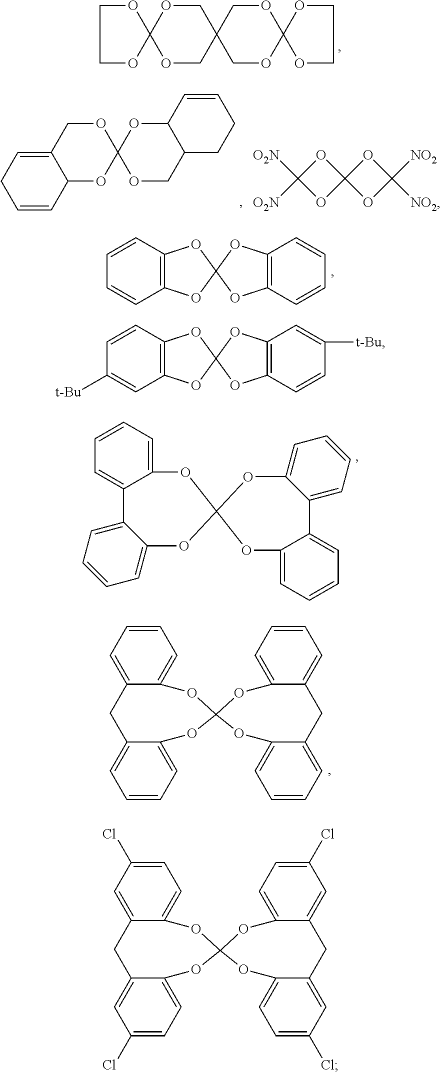

the spiro orthocarbonate compounds as described above undergo a cationic double ring-opening polymerization under the action of an initiator, resulting in an expansion in volume.

Preferably, the unsaturated spiro orthocarbonate monomer and derivatives thereof are selected from at least one of the followings:

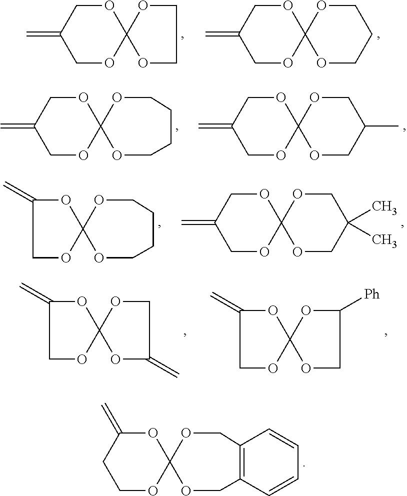

The unsaturated spiro orthocarbonate monomer and derivatives thereof as described above undergo free-radical ring-opening polymerization under the action of an initiator, wherein 3,9-dimethylene-1,5,7,11-tetraoxaspiro[5,5]undecane can undergo a cationic ring-opening polymerization reaction as well as a free-radical ring-opening polymerization reaction.

Wherein the bicyclic orthoester compound comprises a bicyclic orthoester monomer represented by formula IV and derivatives thereof;

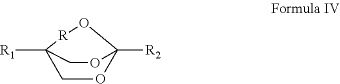

in formula IV, R=—(CH₂)ₙ—, n=0 or 1;
R₁=hydrogen, alkyl, haloalkyl, phenyl, alkylhydroxyl, nitro, amine or ester group;
R₂=hydrogen, alkyl, haloalkyl, phenyl, halophenyl, tolyl or methoxyphenyl;
wherein R₁ and R₂ may be the same group or may also be different groups.
In addition, there are some derivatives prepared by using the functional groups on the ring. Preferably, the derivatives of the bicyclic orthoester monomer are selected from the followings:

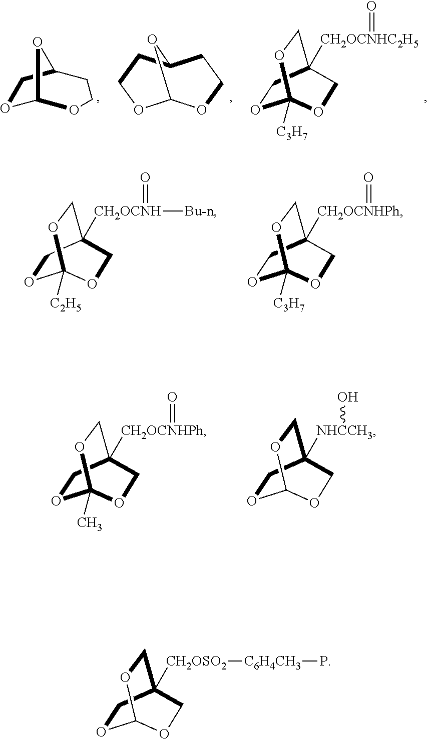

Different from spiro orthoester and spiro orthocarbonate, the opening of the first ring increases the size of the molecular chain when the bicyclic orthoester is undergoing a ring-opening polymerization reaction, however, a cyclical structure is formed, where molecules are easily arranged closely, and thus a large volume shrinkage occurs. When the second ring is opened, a branched structure is created, resulting in a decrease in the density of the polymer, thereby creating an expansion effect. The expansion effect in polymerization of bicyclic orthoester is relatively small relative to spiro orthoester and spiro orthocarbonate.

Wherein the bicyclic lactone compound is a bicyclic lactone monomer represented by formula V;

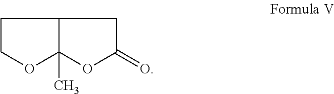

Cases where bicyclic lactone monomers can be expansion polymerized are relatively few.

Wherein the oligomer is an epoxy resin oligomer;

preferably, the oligomer is a silicon-containing epoxy resin oligomer;
preferably, the expansion polymerization imprint resist for nano-imprinting further comprises a cross-linking agent, which undergoes a cross-linking reaction with the oligomer and the expansion monomer to form a network structure;
preferably, the cross-linking agent contains at least one epoxy group;
preferably, the number of the epoxy groups is 4 or more;
preferably, the expansion polymerization imprint resist for nano-imprinting further comprises a demolding agent for reducing the adhesion between the imprint resist system and the template during the nanoimprint demolding process;
preferably, the expansion polymerization imprint resist for nano-imprinting further comprises one selected from the group consisting of a defoaming agent, a leveling agent, a dispersing agent, a matting agent and a polymerization inhibitor, or a combination of at least two thereof, to increase the performances of the imprint resist system in production, application, transportation and storage.

Numbers of factors, such as viscosity, light curing rate, physical and mechanical properties, glass transition temperature of the oligomer and curing shrinkage of the oligomer need to be comprehensively considered when selecting oligomers. Conventional oligomers used for UV curing comprise photosensitive resins such as unsaturated polyesters, epoxy acrylates, urethane acrylates, polyester acrylates, polyether acrylates, pure acrylic resins, silicone oligomers, epoxy resins and the like, which is divided into free-radical polymerization system and cationic polymerization system according to different photoinitiation mechanism. Wherein common free-radical polymeric oligomers are epoxy(methyl)acrylates, urethane(methyl)acrylates and polyester(methyl)acrylates, etc. Common cationic polymeric oligomers are mainly epoxy resins. In view of the difficulties of copolymerization between monomers with different functional groups and the fact that the epoxy resins have features of low curing shrinkage and being not affected by the oxygen inhibition, epoxy resin oligomers are preferred in the present invention. In particular, silicon-containing epoxy resin oligomers are preferred. Thin films formed after such oligomers being cured have a low surface energy, which facilitates demolding, and thus reducing the defects in pattern replication resulting from demolding. Meanwhile, thin films formed after the silicon-containing epoxy resin oligomers being cured generally have a higher resistance to etching, facilitating the transfer of the patterns to the substrate.

The present invention has the following advantages compared with the prior art: firstly, after introducing the expansion monomer into the expansion polymerization imprint resist for nano-imprinting, the expansion monomer can be copolymerized with the oligomer, and the volume change of the imprint resist after polymerization can be adjusted, thus reducing or even eliminating the volume shrinkage of the imprint resist after being cured. An imprint resist with no shrinkage or volume expansion after being cured can be obtained by adjusting the content of the expansion monomer. Secondly, the pressure inside the imprint resist resulting from the shrinkage can be eliminated after adding the expansion monomer, thus improving the adhesion degree between the imprint resist and the substrate. Lastly, the reduced volume shrinkage resulting from the expansion monomer facilitates the reduction of the capability of demolding, thereby reducing the defects in pattern replication due to the demolding.

The imprint resist can effectively reduce the residual stress in the micro-nano pattern, thus can reduce the occurrence of pattern defects in the nanoimprint demolding process caused by the residual stress while achieving accurate pattern replication.

In addition, imprint patterns have high pattern fidelity when the imprint resist is used for nano-imprinting.

### DESCRIPTION OF THE DRAWINGS

FIG. 1 is a microscope image of an imprint pattern obtained according to Example 2 of the present invention;

FIG. 2 is an atomic force microscope image (i.e. an AFM image) of an imprint pattern obtained according to Example 2 of the present invention.

### DETAILED DESCRIPTION

The present invention will be further described in detail with reference to the examples and the accompanying drawings.

### Example 1: A Mixed Imprint Resist System of Spiro Orthocarbonate and Epoxy Resin

Raw materials required for the preparation of the expansion polymerization imprint resist for nano-imprinting in this example comprise an oligomer, an expansion monomer and a photoinitiator, wherein the oligomer is an epoxy resin monomer, the expansion monomer is a spiro orthocarbonate compound, specifically is 2,4,8,10-tetramethyl-1,5,7,11-tetraoxaspiro[5,5]undecane having a structure as shown in formula VI, and the photoinitiator is triaryliodonium salt.

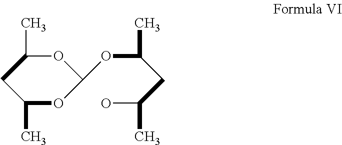

The preparation process of the expansion polymerization imprint resist for nano-imprinting of the present example is as following: the epoxy resin oligomer, the expansion monomer 2,4,8,10-tetramethyl-1,5,7,11-tetraoxaspiro[5,5]undecane and the triaryliodonium salt photoinitiator were uniformly mixed when avoiding light. The weight percentage of the oligomer, expansion monomer and photoinitiator were 90 wt %, 9 wt % and 1 wt %, respectively. In the present example, 2,4,8,10-tetramethyl-1,5,7,11-tetraoxyspiro[5,5]undecane was prepared by using the reaction of di-n-butyl tin ester and carbon disulfide. Besides this method, three other methods, i.e. the transesterification reaction, the reaction of alkoxy thallium compound and carbon disulfide and the reaction of sodium diol and nitromethane can be used.

The imprint resist as described above was dropped on a substrate. The contact angle of the imprint resist liquid droplets and the substrate was measured by using a contact angle measuring instrument, and the contact angle was converted to the volume of the liquid droplet, designated as V₁. The imprint resist liquid droplets as described above were exposed to UV light. The contact angle was measured by a contact angle measuring instrument after curing, and converted to volume, designated as Vₛ. The shrinkage rate, (V₁−Vₛ)/V1, was 1.6%, which decreased by 55% compared with the shrinkage when no expansion monomer was added.

### Example 2: A Mixed Imprint Resist System of Spiro Orthocarbonate and Silicon-Containing Epoxy Resin

Raw materials required for the preparation of the expansion polymerization imprint resist for nano-imprinting in this example comprise an oligomer, an expansion monomer, a photoinitiator and a diluent, wherein the oligomer is a silicon-containing epoxy resin monomer, the expansion monomer is a spiro orthocarbonate compound, specifically is 1,5,7,11-tetraoxaspiro[5,5]undecane having a structure as shown in formula VII, the photoinitiator is triaryliodonium salt, and the diluent is PGMEA.

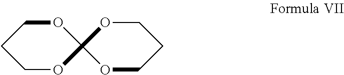

The preparation process of the expansion polymerization imprint resist for nano-imprinting of the present example is as following: the silicon-containing epoxy resin oligomer, the expansion monomer 1,5,7,11-tetraoxaspiro[5,5]undecane, the photoinitiator and the diluent PGMEA were uniformly mixed when avoiding light. The weight percentage of the oligomer, expansion monomer, photoinitiator and diluent were 20 wt %, 19 wt %, 1 wt % and 60 wt %, respectively. In the present example, 1,5,7,11-tetraoxyspiro[5,5]undecane was prepared by using the transesterification reaction. Besides this method, three other methods, i.e. the reaction of tri-n-butyl tin ester and carbon disulfide, the reaction of alkoxy thallium compound and carbon disulfide and the reaction of sodium diol and nitromethane can be used.

The imprint resist as described above was dropped on a substrate. The contact angle of the imprint resist liquid droplets and the substrate was measured by using a contact angle measuring instrument, and the contact angle was converted to the volume of the liquid droplet, designated as V₁. The imprint resist liquid droplets as described above were exposed to UV light. The contact angle was measured by a contact angle measuring instrument after curing, and converted to volume, designated as Vₛ. The shrinkage rate, (V₁−Vₛ)/V₁, was 0.

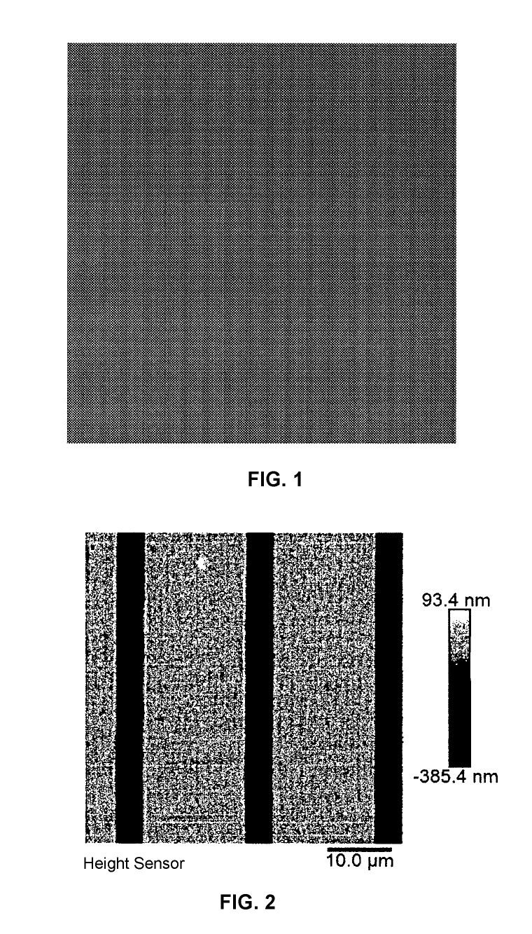

Before the imprint resist was spin-coated, a polymer film which was not soluble in PGMEA was firstly spin-coated on the substrate and then the imprint resist was spin-coated. The pre-spin coating of polymer thin film can prevent the imprint glue from wetting, which facilitate obtaining a uniform imprint glue thin film. Meanwhile, the polymer film can be used as an intermediate layer in pattern transferring. After removing the diluent by soft baking the liquid thin film, the imprinting was performed at room temperature under low pressure, and the film was exposed to UV at a wavelength of 365 nm. Five minutes later, the template was separated from the imprint resist to obtain a complete imprint pattern with imprint lines having a cycle width of 20 μm and a raised width of 15 The surface morphology of the imprint pattern was observed by using a microscope and an AFM at a magnification of 50 times, as shown in FIG. 1 and FIG. 2, respectively.

### Example 3: A Mixed Imprint Resist System of Spiro Orthocarbonate and Silicon-Containing Epoxy Resin

Raw materials required for the preparation of the expansion polymerization imprint resist for nano-imprinting in this example comprise an oligomer, an expansion monomer, a photoinitiator and a diluent, wherein the oligomer is a silicon-containing epoxy resin monomer, the expansion monomer is a spiro orthocarbonate compound, specifically is 1,5,7,11-tetraoxaspiro[5,5]undecane having a structure as shown in formula VII, the photoinitiator is triaryliodonium salt, and the diluent is epoxy cationic active diluent.

The preparation process of the expansion polymerization imprint resist for nano-imprinting of the present example is as following: the silicon-containing epoxy resin oligomer, the expansion monomer 1,5,7,11-tetraoxaspiro[5,5]undecane, the photoinitiator and the diluent were uniformly mixed when avoiding light. The weight percentage of the oligomer, expansion monomer, photoinitiator and diluent were 20 wt %, 35 wt %, 1 wt % and 44 wt %, respectively. In the present example, 1,5,7,11-tetraoxyspiro[5,5]undecane was prepared by using the transesterification reaction. Besides this method, three other methods, i.e. the reaction of tri-n-butyl tin ester and carbon disulfide, the reaction of alkoxy thallium compound and carbon disulfide and the reaction of sodium diol and nitromethane can be used.

The imprint resist as described above was dropped on a substrate. The contact angle of the imprint resist liquid droplets and the substrate was measured by using a contact angle measuring instrument, and the contact angle was converted to the volume of the liquid droplet, designated as V₁. The imprint resist liquid droplets as described above were exposed to UV light. The contact angle was measured by a contact angle measuring instrument after curing, and converted to volume, designated as Vₛ. The shrinkage rate, (V₁−Vₛ)/V₁, was 1%, which decreased by 70% compared with the shrinkage when no expansion monomer was added.

### Example 4: A Mixed Imprint Resist System of Spiro Orthocarbonate and Silicon-Containing Epoxy Resin

Raw materials required for the preparation of the expansion polymerization imprint resist for nano-imprinting in this example comprise an oligomer, an expansion monomer, a photoinitiator, a cross-linking agent and a diluent, wherein the oligomer is a silicon-containing epoxy resin monomer, the expansion monomer is a spiro orthocarbonate compound, specifically is 1,4,6,9-tetraoxaspiro[4,4]nonane having a structure as shown in formula VIII, the photoinitiator is triaryliodonium salt, the cross-linking agent is silicon-containing epoxy resin monomer containing four epoxy groups and the diluent is PGMEA.

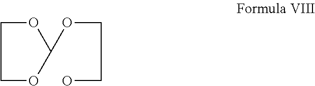

The preparation process of the expansion polymerization imprint resist for nano-imprinting of the present example is as following: the silicon-containing epoxy resin oligomer, the expansion monomer 1,4,6,9-tetraoxaspiro[4,4]nonane, the triaryliodonium salt photoinitiator, the cross-linking agent and the diluent were uniformly mixed when avoiding light. The weight percentage of the oligomer, expansion monomer, photoinitiator, cross-linking agent and diluent were 12 wt %, 22 wt %, 1 wt %, 5 wt % and 60% respectively. In the present example, 1,4,6,9-tetraoxaspiro[4,4]nonane was prepared by using the reaction of di-n-butyl tin ester and carbon disulfide. Besides this method, three other methods, i.e. the transesterification reaction, the reaction of alkoxy thallium compound and carbon disulfide and the reaction of sodium diol and nitromethane can be used.

The imprint resist as described above was dropped on a substrate. The contact angle of the imprint resist liquid droplets and the substrate was measured by using a contact angle measuring instrument, and the contact angle was converted to the volume of the liquid droplet, designated as V₁. The imprint resist liquid droplets as described above were exposed to UV light. The contact angle was measured by a contact angle measuring instrument after curing, and converted to volume, designated as Vₛ. The shrinkage rate, (V₁−Vₛ)/V₁, was 1.5%, which decreased by 57% compared with the shrinkage when no expansion monomer was added.

### Example 5: A Mixed Imprint Resist System of Spiro Orthoester and Silicon-Containing Epoxy Resin

Raw materials required for the preparation of the expansion polymerization imprint resist for nano-imprinting in this example comprise an oligomer, an expansion monomer, a photoinitiator, a cross-linking agent and a diluent, wherein the oligomer is a silicon-containing epoxy resin monomer, the expansion monomer is a spiro orthoester compound, specifically is 1,4,6-trioxaspiro[4,4]nonane having a structure as shown in formula IX, the photoinitiator is triaryliodonium salt, the cross-linking agent is silicon-containing epoxy resin monomer containing four epoxy groups and the diluent is PGMEA.

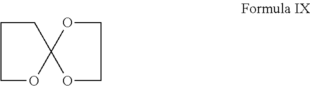

The preparation process of the expansion polymerization imprint resist for nano-imprinting of the present example is as following: the silicon-containing epoxy resin oligomer, the expansion monomer 1,4,6-trioxaspiro[4,4]nonane, the triaryliodonium salt photoinitiator, the cross-linking agent and the diluent were uniformly mixed when avoiding light. The weight percentage of the oligomer, expansion monomer, photoinitiator, cross-linking agent and diluent were 17 wt %, 17 wt %, 1 wt %, 5 wt % and 60% respectively. In the present example, 1,4,6-trioxaspiro[4,4]nonane was prepared by using the reaction of lactone and oxidized alkylene. Besides this method, an addition reaction of unsaturated acetal can also be used.

The imprint resist as described above was dropped on a substrate. The contact angle of the imprint resist liquid droplets and the substrate was measured by using a contact angle measuring instrument, and the contact angle was converted to the volume of the liquid droplet, designated as V₁. The imprint resist liquid droplets as described above were exposed to UV light. The contact angle was measured by a contact angle measuring instrument after curing, and converted to volume, designated as Vₛ. The shrinkage rate, (V₁−Vₛ)/V₁, was 1.8%, which decreased by 49% compared with the shrinkage when no expansion monomer was added.

### Example 6: A Mixed Imprint Resist System of Bicyclic Orthoester and Silicon-Containing Epoxy Resin

Raw materials required for the preparation of the expansion polymerization imprint resist for nano-imprinting in this example comprise an oligomer, an expansion monomer, a photoinitiator, a cross-linking agent and a diluent, wherein the oligomer is a silicon-containing epoxy resin monomer, the expansion monomer is a bicyclic orthoester compound, specifically is 2,6,7-trioxaspiro[2,2,1]heptane having a structure as shown in formula X, the photoinitiator is diaryliodonium salt, the cross-linking agent is silicon-containing epoxy resin monomer containing four epoxy groups and the diluent is PGMEA.

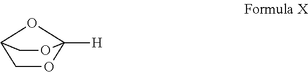

The preparation process of the expansion polymerization imprint resist for nano-imprinting of the present example is as following: the silicon-containing epoxy resin oligomer, the expansion monomer 2,6,7-trioxaspiro[2,2,1]heptane, the diaryliodonium salt photoinitiator, the cross-linking agent and the diluent were uniformly mixed when avoiding light. The weight percentage of the oligomer, expansion monomer, photoinitiator, cross-linking agent and diluent were 22 wt %, 22 wt %, 1 wt %, 5 wt % and 50% respectively. In the present example, 2,6,7-trioxaspiro[2,2,1]heptane was prepared by using the exchange reaction of orthoester and triol.

The imprint resist as described above was dropped on a substrate. The contact angle of the imprint resist liquid droplets and the substrate was measured by using a contact angle measuring instrument, and the contact angle was converted to the volume of the liquid droplet, designated as V₁. The imprint resist liquid droplets as described above were exposed to UV light. The contact angle was measured by a contact angle measuring instrument after curing, and converted to volume, designated as Vₛ. The shrinkage rate, (V₁−Vₛ)/V₁, was 2.1%, which decreased by 40% compared with the shrinkage when no expansion monomer was added.

### Example 7: A Mixed Imprint Resist System of Bicyclic Lactone and Silicon-Containing Epoxy Resin

Raw materials required for the preparation of the expansion polymerization imprint resist for nano-imprinting in this example comprise an oligomer, an expansion monomer, a photoinitiator and a diluent, wherein the oligomer is a silicon-containing epoxy resin monomer, the expansion monomer is a bicyclic lactone having a structure as shown in formula XI, the photoinitiator is triaryliodonium salt and the diluent is PGMEA.

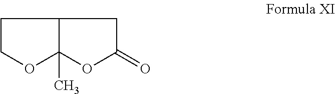

The preparation process of the expansion polymerization imprint resist for nano-imprinting of the present example is as following: the silicon-containing epoxy resin oligomer, the bicyclic lactone expansion monomer, the photoinitiator and the diluent were uniformly mixed when avoiding light. The weight percentage of the oligomer, expansion monomer, photoinitiator and diluent were 24 wt %, 25 wt %, 1 wt % and 50% respectively.

The imprint resist as described above was dropped on a substrate. The contact angle of the imprint resist liquid droplets and the substrate was measured by using a contact angle measuring instrument, and the contact angle was converted to the volume of the liquid droplet, designated as V₁. The imprint resist liquid droplets as described above were exposed to UV light. The contact angle was measured by a contact angle measuring instrument after curing, and converted to volume, designated as Vₛ. The shrinkage rate, (V₁−Vₛ)/V₁, was 2.5%, which decreased by 28% compared with the shrinkage when no expansion monomer was added.

The above contents are only preferred examples of the present invention, and those skilled in the art may make modifications to the specific embodiments and application scope according to the concept of the present invention, and the contents of the specification should not be construed as a limitation to the present invention.

What is claimed is:

1. An expansion polymerization imprint resist for nano-imprinting, raw materials required for the preparation of which comprise an oligomer, wherein the raw materials further comprise an expansion monomer.

2. The expansion polymerization imprint resist for nano-imprinting according to claim 1, wherein the expansion monomer accounts for 10-200% of the weight of the oligomer.

3. The expansion polymerization imprint resist for nano-imprinting according to claim 1, wherein the expansion monomer is one selected from the group consisting of spiro orthoester compound, spiro orthocarbonate compound, bicyclic orthoester compound and bicyclic lactone compound, or a mixture of at least two thereof.

4. The expansion polymerization imprint resist for nano-imprinting according to claim 3, wherein the spiro orthoester compound is selected from the spiro orthoester monomer represented by formula I or derivatives thereof, the unsaturated spiro orthoester monomer represented by formula II or derivatives thereof; 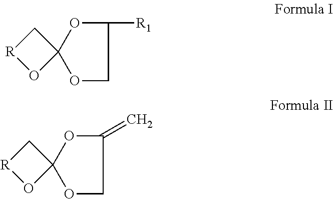
in formula I, R=—(CH₂)ₙ—, n=2, 3 or 4;
R₁=hydrogen, alkyl, haloalkyl, phenyl, anisyl or o-methyl anisyl;
in formula II, R=—(CH₂)ₙ—, n=2, 3 or 4.

5. The expansion polymerization imprint resist for nano-imprinting according to claim 3, wherein the spiro orthocarbonate compound is selected from the spiro orthocarbonate monomer represented by formula III or derivatives thereof, an unsaturated spiro orthocarbonate monomer or derivatives thereof; 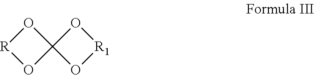
in formula III, R=—(CH₂)ₙ—, n=1, 2, 3, 4;
R₁=—(CH₂)ₙ—, n=1, 2, 3, 4.

6. The expansion polymerization imprint resist for nano-imprinting according to claim 3, wherein the bicyclic orthoester compound comprises a bicyclic orthoester monomer represented by formula IV and derivatives thereof; 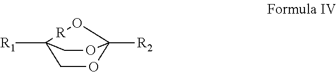
in formula IV, R=—(CH₂)ₙ—, n=0 or 1;
R₁=hydrogen, alkyl, haloalkyl, phenyl, alkylhydroxyl, nitro, amine or ester group;
R₂=hydrogen, alkyl, haloalkyl, phenyl, halophenyl, tolyl or methoxyphenyl.

7. The expansion polymerization imprint resist for nano-imprinting according to claim 3, wherein the bicyclic lactone compound is a bicyclic lactone monomer represented by formula V;

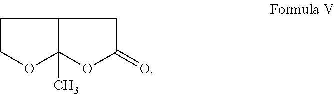

8. The expansion polymerization imprint resist for nano-imprinting according to claim 1, wherein the raw materials further comprise a photoinitiator, which accounts for 0.1-5% of the total weight of the oligomer and the expansion monomer.

9. The expansion polymerization imprint resist for nano-imprinting according to claim 1, wherein the raw materials further comprise a diluent, which is added at such an amount that the viscosity of the imprint resist is allowed to be 1-10000 cP.

10. The expansion polymerization imprint resist for nano-imprinting according to claim 1, wherein the oligomer is an epoxy resin oligomer;

11. The expansion polymerization imprint resist for nano-imprinting according to claim 4, wherein the derivatives of the spiro orthoester monomer are selected from at least one of the followings:

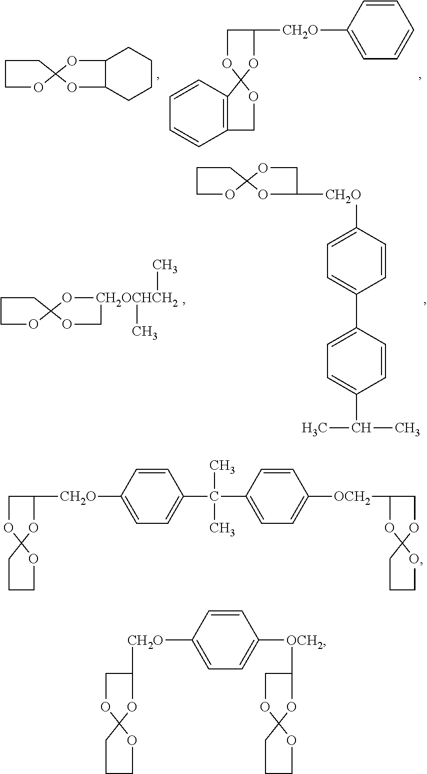

12. The expansion polymerization imprint resist for nano-imprinting according to claim 5, wherein the derivatives of the spiro orthocarbonate monomer are selected from at least one of the followings:

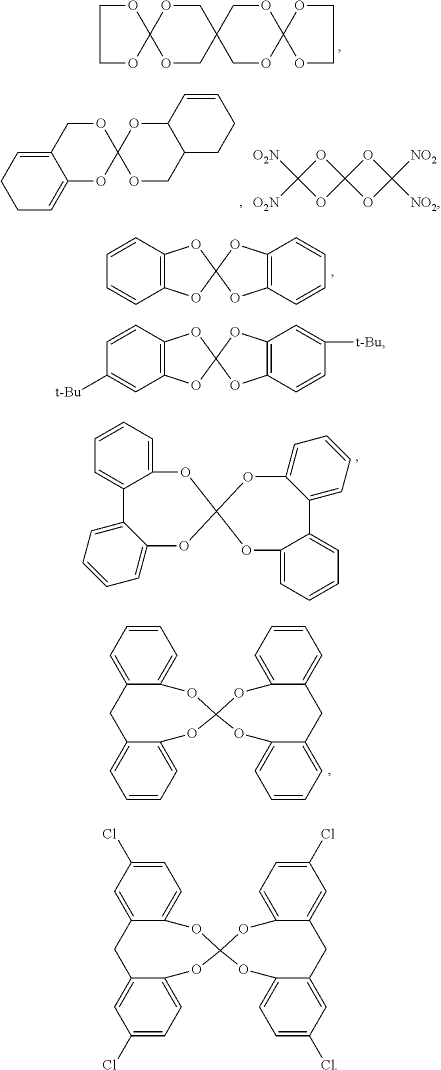

13. The expansion polymerization imprint resist for nano-imprinting according to claim 5, wherein the unsaturated spiro orthocarbonate monomer and derivatives thereof are selected from at least one of the followings:

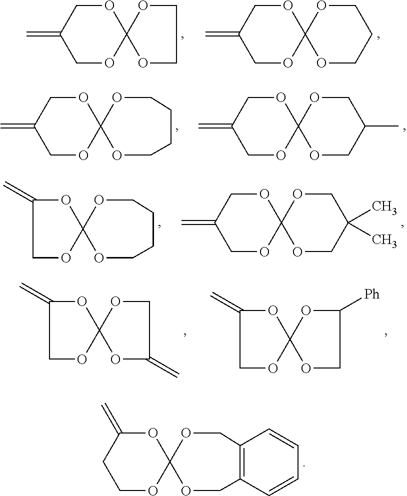

14. The expansion polymerization imprint resist for nano-imprinting according to claim 6, wherein the derivatives of the bicyclic orthoester monomer are selected from the followings:

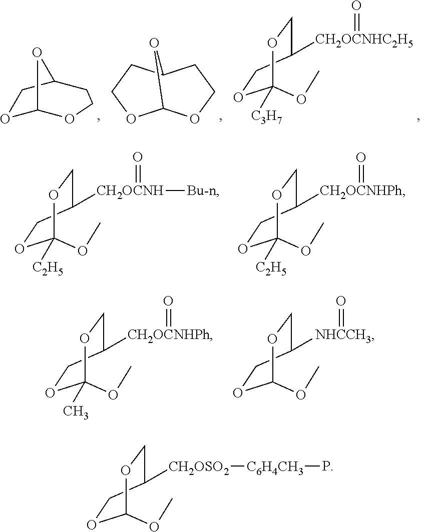

15. The expansion polymerization imprint resist for nano-imprinting according to claim 8, wherein the photoinitiator is a cationic photoinitiator.

16. The expansion polymerization imprint resist for nano-imprinting according to claim 8, wherein the photoinitiator is one selected from the group consisting of aryldiazonium salt, diaryliodonium salt, triarylsulfonium salt and aryl ferrocenium salt, or a mixture of at least two thereof.

17. The expansion polymerization imprint resist for nano-imprinting according to claim 1, wherein the raw materials for preparing the expansion polymerization imprint resist for nano-imprinting further comprise a cross-linking agent.

18. The expansion polymerization imprint resist for nano-imprinting according to claim 17, wherein the cross-linking agent contains at least one epoxy group.

19. The expansion polymerization imprint resist for nano-imprinting according to claim 1, wherein the raw materials for preparing the expansion polymerization imprint resist for nano-imprinting further comprise a demolding agent.

20. The expansion polymerization imprint resist for nano-imprinting according to claim 1, wherein the expansion polymerization imprint resist for nano-imprinting further comprises one selected from the group consisting of a defoaming agent, a leveling agent, a dispersing agent, a matting agent and a polymerization inhibitor, or a combination of at least two thereof.
